(19) United States
(12) Patent Application Publication
(10) Pub. No.: US 2009/0081828 A1
(43) Pub. Date: Mar. 26, 2009

(54) MEMS Fabrication Method

(75) Inventors: Carl B. Freidhoff, New Freedom, PA (US); Silai V. Krishnaswamy, Monroeville, PA (US); William K. Sterrett, Linthicum, MD (US)

Correspondence Address: ROTHWELL, FIGG, ERNST & MANBECK, P.C., 1425 K STREET, N.W., SUITE 800, WASHINGTON, DC, 20005, US

(73) Assignee: NORTHROP GRUMMAN SYSTEMS CORPORATION, Los Angeles, CA (US)

(21) Appl. No.: 11/861,523

(22) Filed: Sep. 26, 2007

(51) Int. Cl. H01L 21/50

(52) U.S. Cl. 438/113; 257/E21.499

(57) ABSTRACT

The present invention provides methods for singulating microelectromechanical systems (MEMS) die from a wafer. A plurality of MEMS devices are formed on the top surface of a wafer, and a plurality of intersecting scribe lanes are then formed, on the bottom surface of the wafer, to define a plurality of dies, each including at least one MEMS device. The intersecting scribe lanes penetrate the wafer to a depth of about 80%, and the wafer is cleaved along the scribe lanes to separate each of the plurality of dies from the wafer.

### FIELD OF THE INVENTION

The present invention relates to microelectromechanical systems (MEMS). More particularly, the present invention relates to MEMS fabrication methods.

### BACKGROUND OF THE INVENTION

Microelectronic and microelectromechanical devices, such as microelectronic integrated circuits (ICs) and MEMS devices, not only offer the advantages attendant to miniaturization, but also afford improvements over the performance of macro scale devices, which generally range in size from tens to hundreds of millimeters (mm). Additionally, MEMS devices may exploit principles that work exclusively on a micro scale, which generally ranges in size from a micrometer (μm, or one-millionth of a meter) to a millimeter. MEMS technology has already been applied to various electromechanical devices, including pressure and inertia sensors, micro-fluidics devices, radio frequency (RF) and optical devices, such as switches, mechanical resonators, phase shifters, etc., and so on.

MEMS devices employ three-dimensional, movable (and/or fixed) mechanical structures, such as cantilevers, membranes, cavities, channels, etc., that are machined using micro-fabrication techniques. Specifically, MEMS devices typically combine surface and/or bulk micro-machined actuating and/or sensing elements with electronic signal processing circuits on a single chip (or die). MEMS technology provides many benefits when compared to macro scale piezoelectric and capacitive devices, such as low cost, stable sensitivity, high reliability, ease of use, etc., as generally noted above.

Microelectronic ICs are solid, compact, and lack these three-dimensional mechanical structures. Consequently, many of the techniques developed for fabricating microelectronic ICs are not readily adaptable to MEMS device fabrication. For example, batch processing of microelectronic IC wafers enables these manufacturers to significantly scale down the size and cost of these devices. However, batch processing of MEMS wafers is difficult and prone to lower yields because the three-dimensional mechanical structures are susceptible to damage caused by the singulation process, which may include dicing, sawing, scribing, drilling, etc., of the wafer. Coating the three-dimensional mechanical structures after they have been released from the substrate, but before the wafer is singulated, is not desirable for several reasons, including the inducement of stiction failures by the subsequent cleaning step. Additionally, releasing each MEMS device (or die) after the wafer is singulated is also not desirable because this would effectively eliminate the benefits derived from batch processing. Accordingly, a method for fabrication of a MEMS device that releases the three-dimensional structure before wafer singulation, and without a post-singulation cleaning step, is highly desirable.

### SUMMARY OF THE INVENTION

Embodiments of the present invention provide methods for singulating microelectromechanical systems (MEMS) die from a wafer. A plurality of MEMS devices are formed on the top surface of a wafer, and a plurality of intersecting scribe lanes are then formed, on the bottom surface of the wafer, to define a plurality of dies, each including at least one MEMS device. The intersecting scribe lanes penetrate the wafer to a depth of about 80%, and the wafer is cleaved along the scribe lanes to separate each of the plurality of dies from the wafer.

### BRIEF DESCRIPTION OF THE DRAWINGS

The above and other advantages of this invention will become more apparent by the following description of invention and the accompanying drawings.

FIG. 1a depicts a top surface of a MEMS wafer, according to an embodiment of the present invention.

FIGS. 1b and 1c depict a top view of a MEMS device, according to an embodiment of the present invention.

FIG. 2a depicts a bottom surface of a MEMS wafer, according to an embodiment of the present invention.

FIG. 2b depicts a cross-sectional view A-A′ of the MEMS wafer of FIG. 2a, according to an embodiment of the present invention.

FIG. 3 presents a flow chart outlining a method for singulating MEMS die from a wafer, according to an embodiment of the present invention.

FIG. 4 depicts a top view of a portion of a MEMS bio-sensor component, according to an embodiment of the present invention.

FIG. 5 presents an isometric view of a miniature mass spectrometer, according to an embodiment of the present invention.

### DETAILED DESCRIPTION

Embodiments of the present invention provide a fabrication method for MEMS devices that advantageously minimizes MEMS die separation force and stress, shortens fabrication cycle time and provides lower cost, higher performance and higher die yields than existing singulation techniques. Many prior art IC die singulation techniques separate individual dies from silicon (Si) wafers by scribing the top surface of the wafer to a certain depth and then applying a force adjacent to these lines to cleave the wafer into individual IC dies. This technique is possible, generally, because Si, and particularly (100) oriented Si, has cleavage planes parallel to the major flats of the wafer. However, MEMS die sizes are on the order of few millimeters on a side. Consequently, this process becomes difficult because greater force is required to cleave the smaller MEMS die, which introduces undesirable stresses in the singulated MEMS device.

Conventional IC dicing, using a dicing saw, for example, typically requires that the top surface of the wafer be protected by a photoresist layer that is removed after dicing by wet chemistry, for example. As discussed above, a MEMS die contains devices that typically include structure that is supported only along the edges, such as cantilevers or diaphragms, which precludes the use of wet chemistry. While it may be possible to remove a protective photoresist layer by dry etching, all of the residue may not be removed from the top surface, which, of course, contaminates the MEMS device. Similarly, scribing the top surface of a wafer with a laser also introduces debris, and the removal of any protective photoresist layer would have the same problems described for conventional IC dicing.

Embodiments of the present invention provide methods for singulating a MEMS die from a wafer by scribing the bottom surface of the wafer to depth of about 80% and then cleaving the wafer along the scribe lanes by applying a force to the top surface of the wafer, which advantageously maintains the cleanliness of the top surface of the wafer, and, therefore, the MEMS devices. A preferred embodiment uses a laser to form intersecting scribe lanes on the bottom surface of a wafer, while additional embodiments advantageously accommodate unique, protruding MEMS die geometries, even in single crystalline substrates, such as Si and gallium arsenide (GaAs).

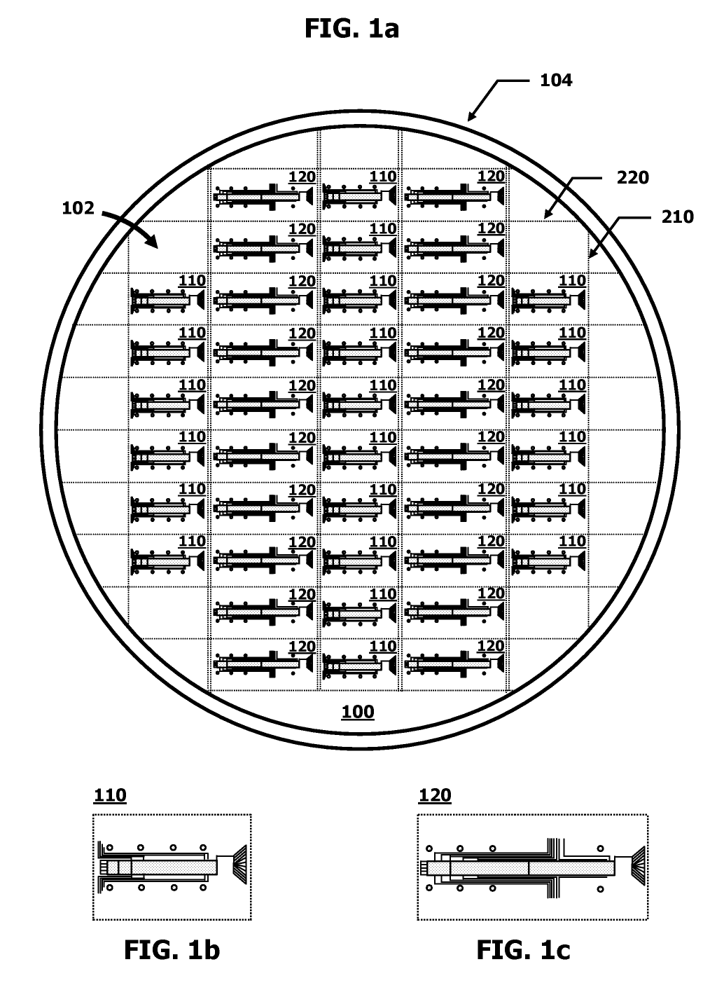

FIG. 1a depicts a top surface of a MEMS wafer, according to an embodiment of the present invention. Wafer 100 is formed from a suitable substrate material, such as Si or GaAs. Preferably, (100) oriented Si is employed, for the reasons noted above. Prior to forming the MEMS devices on top surface 102, wafer 100 may be mounted to carrier 104 in order to facilitate handling, processing, etc. Generally, any number of MEMS devices may be formed on the top surface 102 of wafer 100, using a variety of techniques, such as, for example, bulk micromachining, wet etching, dry etching, surface micromachining, deep reactive ion etching micromachining and micro-molding, etc. Preferably, the MEMS devices are formed in a symmetric lattice or grid arrangement to more easily comport with the inventive die singulation techniques discussed herein. Exemplary MEMS devices include structures on the order of about 100 μm in height.

Two different MEMS devices are depicted in FIG. 1a, i.e., MEMS devices 110 and MEMS devices 120. Each MEMS device 110 is a representation of a medium resolution chemical sensor base chip with a multi-channel detector, while each MEMS device 120 is a representation of a medium to high resolution chemical sensor using the same multi-channel detector array. FIGS. 1b and 1c depict top views of these exemplary devices. FIG. 1b depicts MEMS device 110 after singulation into a die, while FIG. 1c depicts MEMS device 120 after singulation into a die.

As discussed above, wafer 100 may be mounted on a carrier 104, such as, for example, a 6″ Si carrier wafer that has been cut as a doughnut, which supports wafer 100 along its edges. Carrier 104 protects the top side 102 of wafer 100 from any scratches, which eliminates the need to apply photoresist in order to protect the MEMS devices located on top side 102. Advantageously, all debris from the scribing process are deposited on the bottom surface 202 of wafer 100, which further protects the MEMS structures, and their attendant critical surfaces, on the top side 102 of wafer 100.

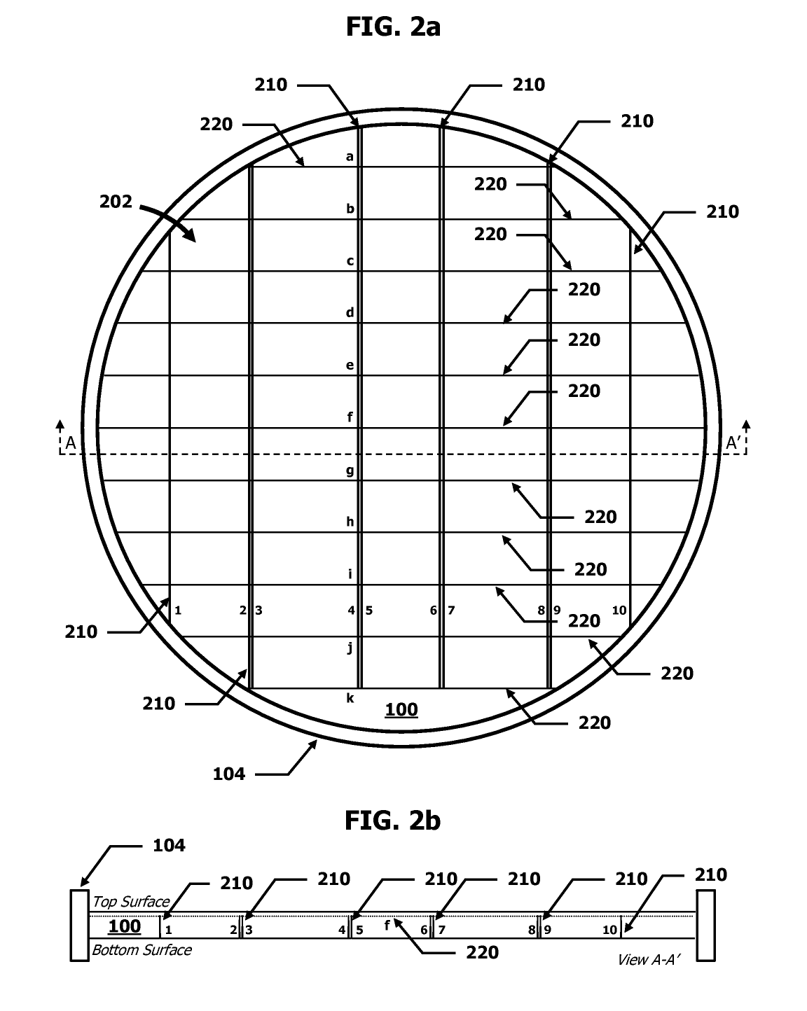

FIG. 2a depicts a bottom surface of a MEMS wafer, according to an embodiment of the present invention. Intersecting scribe lanes 210, 220 are scribed into wafer 100 to a relative depth of about 80% of the thickness of wafer 100. In a preferred embodiment, a Nd-YAG laser (e.g., Laser Corp. Model 4024) operating at 1064 nm, forms scribe lanes 210, 220. In one example, with the laser power set to 0.85 Watts (average) and Q-switched at 2.0 kHz, a four inch wafer can be scribed to a depth of 80% using cutting gas SF6 with a flow rate 10 SCFH, at a feed rate of 0.9 inches per second, in 10 passes. The scribing process is preferably computer controlled, thereby allowing precise alignment of scribe lanes 210, 220 on bottom surface 202 with respect to the layout of MEMS device 110, 120 on top surface 102. For example, optical registration marks may be provided for this purpose. This alignment is indicated in FIG. 1a, which depicts scribe lanes 210, 220 in phantom.

For convenience, scribe lanes 210 are denoted “vertical” lanes, while scribe lanes 220 are denoted “horizontal” lanes. Of course, this nomenclature is arbitrary and not intended to limit the invention in any manner. Scribe lanes 210 include vertical lanes “1” through “10,” while scribe lanes 220 include horizontal lanes “a” through “k”. As clearly shown in FIG. 1a, intersecting scribe lanes 210, 220 form die outlines that will contain MEMS devices after singulation. In the preferred embodiment, scribe lanes 210, 220 are generally straight and orthogonal to one another; other geometries, based on the respective perimeters realized by the MEMS devices, may also be employed. FIG. 2b depicts a cross-sectional view A-A′ of the MEMS wafer of FIG. 2a, according to an embodiment of the present invention. Vertical lanes 210-1 through 210-10, as well as horizontal lane 220-f, are visible.

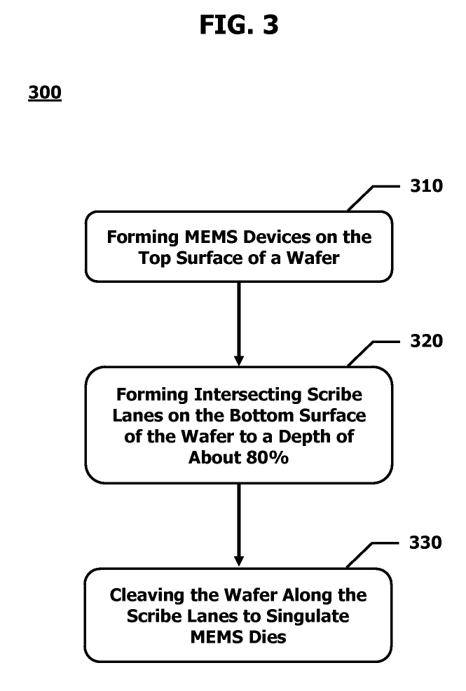

FIG. 3 presents a flow chart outlining a method (300) for singulating MEMS die from a wafer, according to an embodiment of the present invention. As discussed above, MEMS devices 110, 120 are formed (310) on top surface 102 of wafer 100, and intersecting scribe lanes 210,220 are then formed (320) onto bottom surface 202 of wafer 100 to a depth of about 80%. Each die is singulated from wafer 100 by cleaving (330) wafer 100 along scribe lanes 210, 220. In the preferred embodiment, the cleaving process simply applies a small force (or pressure) to top surface 102 to singulate each die. Because the force (or pressure) is applied to top surface 102, the MEMS devices and their respective structures are not subjected to destructive compressive stresses. Other scribing, cleaving and general singulation techniques are also contemplated by the present invention, as known in the art.

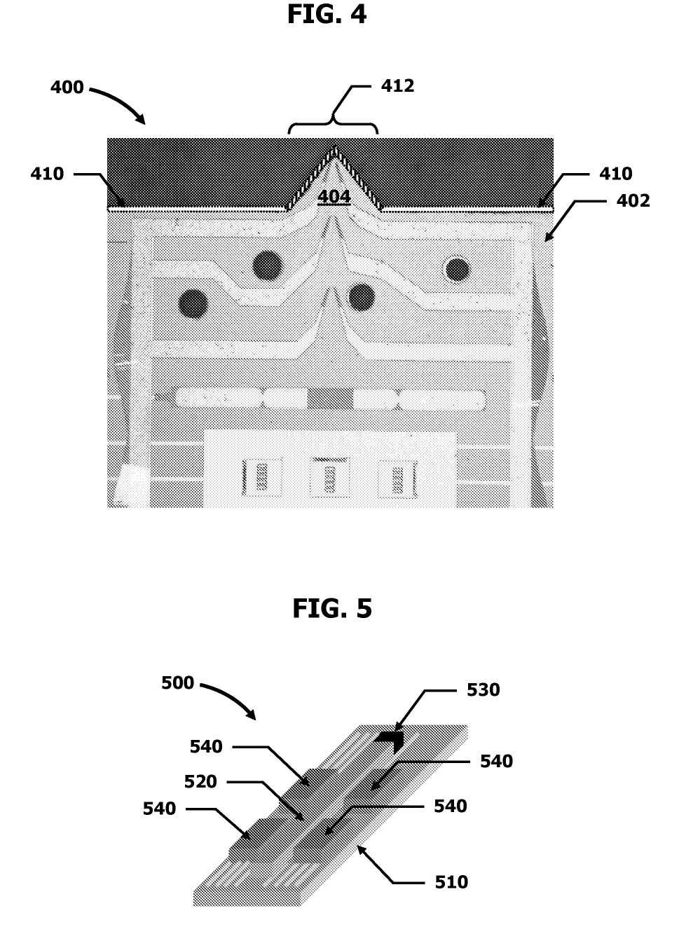

In another embodiment, scribe lanes 210, 220 conform to protrusions extending from the MEMS device. FIG. 4 depicts a top view of a portion of a MEMS bio-sensor component 400, according to an embodiment of the present invention. Base chip 402 includes a triangular-shaped front tip 404 for an electrospray interface for use with biological samples. The front 404 protrudes past the otherwise straight edge of sensor 400. In this embodiment, scribe lane 410 conforms to the perimeter of the front tip 404; this portion is denoted scribe lane portion 414, which is inscribed completely through the wafer, i.e., a depth of 100%. While some debris may be deposited on the front surface of the wafer proximate to scribe lane portion 412, the amount is minimal and the benefits gained during singulation, e.g., reduced stress, less cracking, etc., far outweigh the costs. In one example, over 100 individual bio-sensor pump die have been singulated from a 4 inch Si wafer, in additional to bio-sensor base chip 402 with its non-linear front tip 404 feature. In another example, a MISOC (micromachining of silicon on a chip) device lid having electroplated structures over 100 μm tall on the top side of the wafer has been singulated using these inventive methods. This inventive procedure is quite universal and can be applied to singulation of other parts, such as, for example, GaAs and SiC components.

An exemplary application for the present inventive technique is the fabrication of a mass imaging spectrograph on a chip. This small, portable, inexpensive MEMS-based instrument can be used, inter alia, to detect and identify dangerous chemical and biological molecules locally and in real-time, rather than at a remote location, such as a laboratory. FIG. 5 presents an isometric view of a miniature mass spectrometer, according to an embodiment of the present invention. In this embodiment, mass spectrometer 500 includes different MEMS devices or components, including a sampling orifice (not shown), ionizer (not shown), ion optics (not shown), mass filter base chip 510, mass filter lid chip 520, detector array 530 and vacuum pump modules 540, a portion of which is depicted in FIG. 1. These components are fabricated using the inventive processing techniques described herein, on various 4, 6 or 8 inch diameter silicon substrates.

In another embodiment, the base wafer may contain an ionizer along with portions of the ion optics and the ion collector on a single die. On a single 6 inch silicon wafer, many such base die may be fabricated. The pump and lid die may be fabricated separately, on 4 inch wafers, for example. The detector array is a CMOS-based design, and may be fabricated on 8 inch wafers, for example. After singulating these die, individual parts are inspected and assembled on the base chip using a flip-chip soldering technique. This hybridized assembly is then joined on a mounting substrate to provide connection to power supplies and a controlling microprocessor.

While this invention has been described in conjunction with specific embodiments thereof, many alternatives, modifications and variations will be apparent to those skilled in the art. Accordingly, the preferred embodiments of the invention as set forth herein, are intended to be illustrative, not limiting. Various changes may be made without departing from the true spirit and full scope of the invention as set forth herein.

We claim:

1. A method for singulating microelectromechanical systems (MEMS) die from a wafer, comprising:
forming a plurality of MEMS devices on a top surface of a wafer;
forming a plurality of intersecting scribe lanes, on a bottom surface of the wafer, to define a plurality of dies, the scribe lanes penetrating the wafer to a depth of about 80%; and
cleaving the wafer along the scribe lanes to separate each of the plurality of dies from the wafer, each die including at least one MEMS device.

2. The method of claim 1, wherein forming the plurality of MEMS devices includes at least one of bulk micromachining, wet etching, dry etching, surface micromachining, deep reactive ion etching micromachining and micro-molding.

3. The method of claim 2, wherein the plurality of MEMS devices are released from the wafer prior to cleaving.

4. The method of claim 1, wherein the plurality of intersecting scribe lanes include parallel scribe lanes and perpendicular scribe lanes.

5. The method of claim 1, wherein the scribe lanes are formed using a laser.

6. The method of claim 1, wherein the scribe lanes are formed using a water jet.

7. The method of claim 1, wherein the scribe lanes are formed using a dicing saw.

8. The method of claim 1, wherein cleaving the wafer includes applying a force to the top surface of the wafer proximate to one of the scribe lanes.

9. The method of claim 1, further comprising:
forming a protrusion on at least one side of at least one of the MEMS devices; and
conforming a portion of a scribe lane, proximate to each protrusion, to the perimeter of the protrusion; and
increasing the depth of the conforming portion so that the conforming portion of the scribe lane passes completely through the wafer.

10. The method of claim 1, further comprising mounting the wafer to a carrier prior to forming the plurality of MEMS devices, and removing the wafer from the carrier prior to cleaving.

11. A method for singulating microelectromechanical systems (MEMS) die from a wafer, comprising:
forming a plurality of MEMS devices on a top surface of a wafer, at least one MEMS device having a protrusion on at least one side;
forming a plurality of intersecting scribe lanes, on a bottom surface of the wafer, to define a plurality of dies, the scribe lanes completely penetrating the wafer in the portions proximate to each protrusion and penetrating the wafer to a depth of about 80% in the remaining portions;
releasing the plurality of MEMS devices from the wafer; and
cleaving the wafer along the scribe lanes to separate each of the plurality of dies from the wafer, each die including at least one MEMS device.

12. The method of claim 11, wherein forming the plurality of MEMS devices includes at least one of bulk micromachining, wet etching, dry etching, surface micromachining, deep reactive ion etching micromachining and micro-molding.

13. The method of claim 11, wherein the plurality of intersecting scribe lanes include parallel scribe lanes and perpendicular scribe lanes.

14. The method of claim 11, wherein the scribe lanes are formed using a laser.

15. The method of claim 11, wherein the scribe lanes are formed using a water jet.

16. The method of claim 11, wherein the scribe lanes are formed using a dicing saw.

17. The method of claim 11, wherein cleaving the wafer includes applying a force to the top surface of the wafer proximate to one of the scribe lanes.

18. The method of claim 11, further comprising mounting the wafer to a carrier prior to forming the plurality of MEMS devices, and removing the wafer from the carrier prior to cleaving.
